(19) United States
(12) Patent Application Publication
(10) Pub. No.: US 2025/0079206 A1
(43) Pub. Date: Mar. 6, 2025

(54) INFORMATION PROCESSING APPARATUS, SUBSTRATE PROCESSING APPARATUS, AND INFORMATION PROCESSING METHOD

(71) Applicant: EBARA CORPORATION, Tokyo (JP)

(72) Inventors: Yoshimasa OZONE, Tokyo (JP); Tsuneo TORIKOSHI, Tokyo (JP)

(21) Appl. No.: 18/815,592

(22) Filed: Aug. 26, 2024

(30) Foreign Application Priority Data
Aug. 28, 2023 (JP) 2023-137892

(51) Int. Cl. H01L 21/67; H01L 21/677

(52) U.S. Cl. CPC H01L 21/67219; H01L 21/67742

(57) ABSTRACT

A state of an elastic film in a substrate holding device for a substrate polishing process is properly or easily determined. An information processing apparatus includes an information acquirer that acquires apparatus operation information including polishing process information showing a state of a polishing process of a substrate, and transfer process information showing a state of a transfer process of the substrate, as an operation state at a time of a substrate processing apparatus being operated, and a state determiner that determines elastic film state information with respect to the apparatus operation information by inputting the apparatus operation information acquired by the information acquirer to a learning model that is caused to learn, by machine learning, a correlation between the apparatus operation information, and the elastic film state information showing a state of the elastic film in a top ring at a time of the polishing process and/or the transfer process shown by the apparatus operation information being performed.

### TECHNICAL FIELD

The present invention relates to an information processing apparatus, a substrate processing apparatus, and an information processing method.

### BACKGROUND ART

In manufacture of semiconductor devices, chemical machine polishing (CMP) apparatuses are used to flatten the surfaces of substrates. Substrates used in the manufacture of semiconductor devices are often disk-shaped. Further, the demand for flatness is increasing for not only the semiconductor devices but also for flattening the surfaces of rectangular substrates such as CCL substrates (copper clad laminate substrates), PCB (printed circuit board) substrates, photomask substrates, and display panels. Further, the demand for flattening the surfaces of the package substrates on which electronic devices are disposed such as PCB substrates is increasing.

In the substrate processing apparatus as above, a substrate holding device using an elastic film (membrane) is used to uniformize or adjust a relative pressing force between the substrate that is being polished and the polishing surface of a polishing pad. As one example, a pressure chamber formed of an elastic film (membrane) is provided in a lower portion of a top ring as the substrate holding device, and by supplying gas such as air to the pressure chamber, the substrate is pressed to the polishing surface of the polishing pad and polished.

After finishing the polishing process, the substrate holding device moves to a position above the transfer stage in the state of holding the substrate, and delivers the substrate to the transfer stage. As an example, delivery of the substrate is performed by injecting gas into a gap between the substrate and the elastic film while supplying gas to the pressure chamber, and thereby detaching the substrate from the elastic film. Seating of the substrate on the transfer stage is detected by a plurality of sensors for detecting different locations on the substrate. The substrate placed on the transfer stage is delivered to a swing transporter and is transferred to a subsequent process.

### CITATION LIST

### Patent Literature

PTL 1: Japanese Patent Laid-Open No. 2012-178608

### SUMMARY OF INVENTION

### Technical Problem

The elastic film used in the substrate processing apparatus is worn or deteriorated as a result of repeating substrate polishing. When the elastic film is worn or deteriorated, the substrate processing conditions such as polishing pressure change, and uniformity of the film thickness of the substrate after the polishing process may be impaired. Therefore, maintenance or replacement of the elastic films has been conventionally performed each time the preset number (for example, several hundreds, several thousands) of substrates are held and polished. Here, although it is preferable to increase the maintenance frequency of the elastic films to maintain precision of substrate processing, the processing speed per time of the substrate processing apparatus becomes lower and the running cost increases as the maintenance frequency is higher. Further, wears or deteriorations of the elastic films are individually different. It is conceivable to provide a sensor such as an image sensor in the substrate processing apparatus to acquire the state of the elastic film, and determine the maintenance date for the elastic films, but this can cause increase in the cost of the substrate processing apparatus and slowdown of the processing speed per unit time.

The present invention has been made in view of the above-described problem, and it is an object of the present invention to properly or easily determine a state of an elastic film in a substrate processing apparatus.

### Solution to Problem

According to one embodiment of the present invention, there is proposed an information processing apparatus including an information acquirer that acquires apparatus operation information including polishing process information showing a state of a polishing process, and transfer process information showing a state of a transfer process, as an operation state at a time of a substrate processing apparatus being operated, the substrate processing apparatus including a polishing table that supports a polishing pad, a top ring including an elastic film composing a substrate holding surface and a pressure chamber, and a transfer stage configured so that a substrate is delivered thereto from the top ring, and performing the polishing process of pressing the substrate to the polishing pad according to a fluid supplied to the pressure chamber, and the transfer process of detaching the substrate from the clastic film and delivering the substrate to the transfer stage, and a state determiner that determines elastic film state information with respect to the apparatus operation information by inputting the apparatus operation information acquired by the information acquirer to a learning model that is caused to learn, by machine learning, a correlation between the apparatus operation information, and the elastic film state information showing a state of the elastic film at a time of the polishing process and/or the transfer process shown by the apparatus operation information being performed.

According to one embodiment of the present invention, there is proposed an information processing method including an information acquiring step of acquiring apparatus operation information including polishing process information showing a state of a polishing process, and transfer process information showing a state of a transfer process, as an operation state at a time of a substrate processing apparatus being operated, the substrate processing apparatus including a polishing table that supports a polishing pad, a top ring including an elastic film composing a substrate holding surface and a pressure chamber, and a transfer stage configured so that a substrate is delivered thereto from the top ring, and performing the polishing process of pressing the substrate to the polishing pad according to a fluid supplied to the pressure chamber, and the transfer process of detaching the substrate from the elastic film and delivering the substrate to the transfer stage, and a state determination step of determining an elastic film state information with respect to the apparatus operation information by inputting the apparatus operation information acquired by the information acquirer to a learning model that is caused to learn, by machine learning, a correlation between the apparatus operation information, and the clastic film state information showing a state of the elastic film at a time of the polishing process and/or the transfer process shown by the apparatus operation information being performed.

### BRIEF DESCRIPTION OF DRAWINGS

FIG. 1 is a plan view showing an entire configuration of a substrate processing apparatus according to one embodiment of the present invention;

FIG. 2 is a schematic view showing a configuration of a polishing module according to the present embodiment;

FIG. 3 is a schematic sectional view of a top ring configuring a substrate holding device that holds a wafer to be polished and press the wafer to a polishing surface on a polishing table;

FIG. 4 is a schematic view showing a substrate delivery device from above; FIG. 5A is a schematic view showing a delivery process of a wafer to the substrate delivery device from the top ring;

FIG. 5B is a schematic view showing the delivery process of the wafer to the substrate delivery device from the top ring;

FIG. 5C is a schematic view showing the delivery process of the wafer to the substrate delivery device from the top ring;

FIG. 6 is a schematic functional block diagram of a controller in the present embodiment;

FIG. 7 is a schematic functional block diagram of a machine learning device in the present embodiment;

FIG. 8 is a time chart showing an example of a detection signal of each sensor at a time of detaching a wafer;

FIG. 9 is a diagram showing an example of a time difference in seating timing of each wafer; and

FIG. 10 is a diagram schematically showing an example of detaching time of each wafer.

### DESCRIPTION OF EMBODIMENTS

Hereinafter, embodiments of an information processing apparatus, a substrate processing apparatus, and an information processing method according to the present invention will be described with the accompanying drawings. In the accompanying drawings, the same or similar elements are assigned with the same or similar reference sings, and redundant explanation concerning the same or similar elements may be omitted in explanation of each of the embodiments. Furthermore, features shown in each of the embodiments are also applicable to other embodiments unless they are mutually inconsistent.

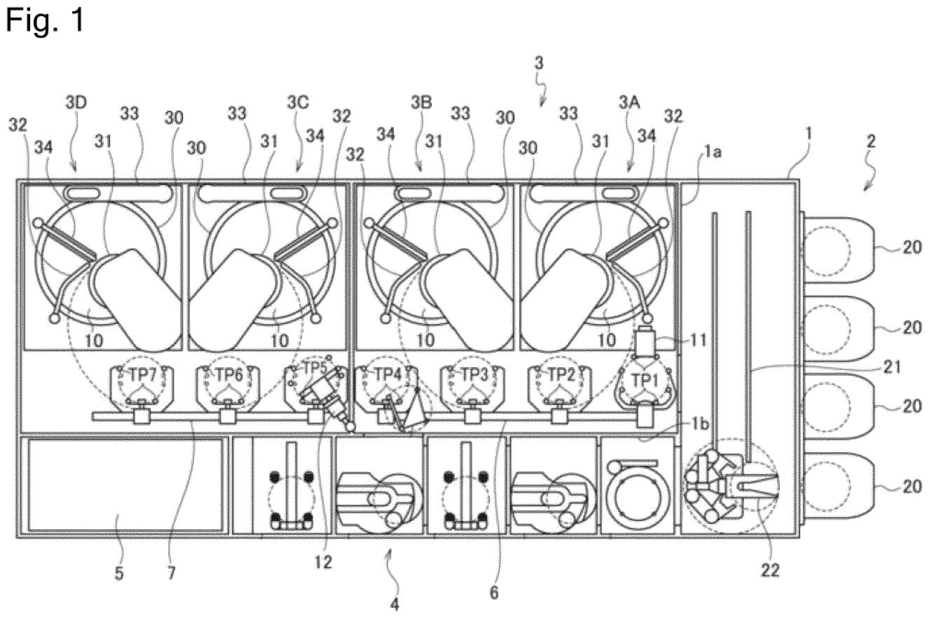

FIG. 1 is a plan view showing an entire configuration of a substrate processing apparatus according to one embodiment of the present invention. As shown in FIG. 1, the substrate processing apparatus includes a substantially rectangular housing 1, and an inside of the housing 1 is divided into a load port 2, a polishing module 3, and a cleaning module 4 by partition walls 1a and 1b. The load port 2, the polishing module 3, and the cleaning module 4 are each independently assembled and independently evacuated. In addition, the substrate processing apparatus has a controller 5 that controls a substrate processing operation.

The load port 2 includes two or more (four in the present embodiment) front loader 20 on which wafer cassettes that stock a large number of wafers (an example of substrates) are placed. These front loaders 20 are disposed adjacently to the housing 1, and arranged along a width direction (direction perpendicular to a longitudinal direction) of the substrate processing apparatus. On the front loader 20, an open cassette, a SMIF (standard manufacturing interface) pod, or a FOUP (front opening unified pod) can be mounted. Note that the present embodiment is described by using a circular semiconductor wafer as an example of the substrate, but regardless of the example like this, a square substrate may be used, for example.

Further, the load port 2 is provided with a traveling mechanism 21 extending along the arrangement of the front loaders 20. A transfer robot (loader) 22 movable along an arrangement direction of wafer cassettes is placed on the traveling mechanism 21. The transfer robot 22 can have access to the wafer cassettes mounted on the front loaders 20 by moving on the traveling mechanism 21. In the present embodiment, the transfer robot 22 includes two hands up and down. The transfer robot 22 uses an upper hand when returning a processed wafer to the wafer cassette and uses a lower hand when taking out a wafer before processing from the wafer cassette.

The load port 2 is a clean region, and an inside of the load port 2 is maintained at a higher pressure than any of an exterior of the substrate processing apparatus, the polishing module 3, and the cleaning module 4. The polishing module 3 is a dirty region because it uses slurry as a polishing liquid. Inside the polishing module 3, a negative pressure is formed, and pressure thereof is maintained to be lower than an inner pressure of the cleaning module 4.

The polishing module 3 is a region where polishing (flattening) of the wafer is performed, and includes a first polishing module 3A, a second polishing module 3B, a third polishing module 3C, and a fourth polishing module 3D. As shown in FIG. 1, in the present embodiment, the first polishing module 3A, the second polishing module 3B, the third polishing module 3C, and the fourth polishing module 3D are arranged along a longitudinal direction of the substrate processing apparatus. Note that there may be provided one, two, three, five or more polishing modules. Since the first polishing module 3A, the second polishing module 3B, the third polishing module 3C, and the fourth polishing module 3D have same configurations as one another, only the first polishing module 3A will be described hereinafter.

The first polishing module 3A includes a polishing table 30 to which a polishing pad 10 having a polishing surface is attached, and a top ring (substrate holding device) 31 for holding a wafer and polishing the wafer while pressing the wafer to the polishing pad 10 on the polishing table 30. Further, the first polishing module 3A includes a polishing liquid supply nozzle 32 for supplying a polishing liquid and a dressing liquid (for example, pure water) to the polishing pad 10, a dresser 33 for dressing the polishing surface of the polishing pad 10, and an atomizer 34 that atomizes a fluid mixture of a liquid (for example, pure water) and gas (for example, nitrogen gas) or a liquid (pure water, for example) and injects it to the polishing surface.

Next, a transfer mechanism for transferring the wafer will be described. As shown in FIG. 1, a first linear transporter 6 is disposed adjacently to the first polishing module 3A and the second polishing module 3B. The first linear transporter 6 is a mechanism that transfers wafers among four transfer positions (a first transfer position TP1, a second transfer position TP2, a third transfer position TP3, and a fourth transfer position TP4 in order from a load port side) along a direction in which the first polishing module 3A and the second polishing module 3B are arranged.

A second linear transporter 7 is disposed adjacently to the third polishing module 3C and the fourth polishing module 3D. The second linear transporter 7 is a mechanism that transfers wafers among three transfer positions (a fifth transfer position TP5, a sixth transfer position TP6, and a seventh transfer position TP7 in order from the load port side) along a direction in which the third polishing module 3C and the fourth polishing module 3D are arranged.

A wafer is transferred to the first polishing module 3A and the second polishing module 3B by the first linear transporter 6. The top ring 31 of the first polishing module 3A moves between a polishing position and the second transfer position TP2 by a swing operation of a top ring head. Then, delivery of the wafer to the top ring 31 is performed at the second transfer position TP2. Likewise, a top ring 31 of the second polishing module 3B moves between a polishing position and the third transfer position TP3, and delivery of a wafer to the top ring 31 is performed at the third transfer position TP3. A top ring 31 of the third polishing module 3C moves between a polishing position and the sixth transfer position TP6, and delivery of a wafer to the top ring 31 is performed at the sixth transfer position TP6. A top ring 31 of the fourth polishing module 3D moves between a polishing position and the seventh transfer position TP7, and delivery of a wafer to the top ring 31 is performed at the seventh transfer position TP7.

At the first transfer position TP1, a lifter 11 for receiving a wafer from the transfer robot 22 is disposed. The wafer is delivered to the first linear transporter 6 from the transfer robot 22 via the lifter 11. A shutter (not shown) is provided at the partition wall la to be located between the lifter 11 and the transfer robot 22, and during transfer of a wafer, the shutter is opened so that the wafer is delivered to the lifter 11 from the transfer robot 22. Further, among the first linear transporter 6, the second linear transporter 7, and the cleaning module 4, a swing transporter 12 is disposed. The swing transporter 12 has a hand that is movable between the fourth transfer position TP4 and the fifth transfer position TP5, and delivery of a wafer from the first linear transporter 6 to the second linear transporter 7 is performed by the swing transporter 12. A wafer is transferred to the third polishing module 3C and/or the fourth polishing module 3D by the second linear transporter 7. Further, the wafer polished in the polishing module 3 is transferred to the cleaning module 4 via the swing transporter 12.

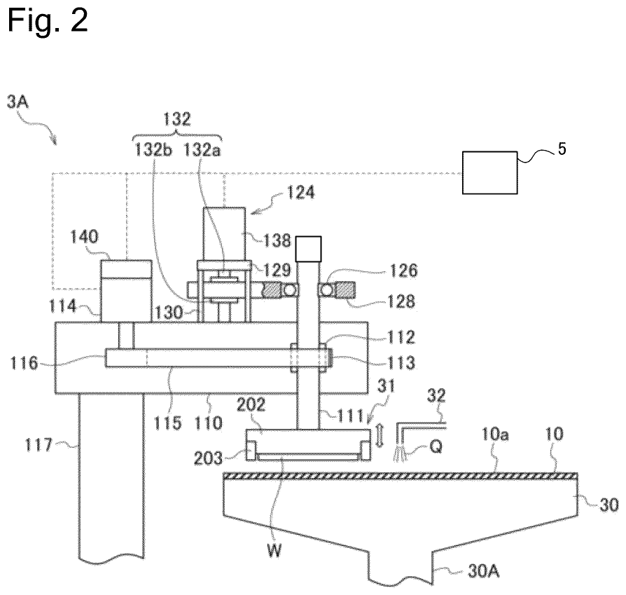

FIG. 2 is a schematic view showing a configuration of the first polishing module 3A according to the present embodiment. As shown in FIG. 2, the first polishing module 3A includes the polishing table 30, and the top ring 31 that holds a substrate such as a wafer to be polished and presses the substrate to the polishing surface on the polishing table. The polishing table 30 is connected to a motor (not shown) that is disposed below it via a table shaft 30A, and is rotatable around the table shaft 30A. The polishing pad 10 is pasted on a top surface of the polishing table 30, and a polishing surface 10a of the polishing pad 10 composes the polishing surface that polishes a wafer W. The polishing liquid supply nozzle 32 is installed above the polishing table 30, and a polishing liquid Q is supplied onto the polishing pad 10 on the polishing table 30 by the polishing liquid supply nozzle 32.

The top ring 31 includes a top ring body 202 that presses the wafer W to the polishing surface 10a, and a retainer ring 203 that holds an outer peripheral edge of the wafer W to prevent the wafer W from protruding from the top ring.

The top ring 31 is connected to a top ring shaft 111, and the top ring shaft 111 moves up and down with respect to the top ring head 110 by an up-down movement mechanism 124. By up-down movement of the top ring shaft 111, the entire top ring 31 is caused to ascend and descend to be positioned with respect to the top ring head 110.

The up-down movement mechanism 124 that moves the top ring shaft 111 and the top ring 31 up and down includes a bridge 128 that rotatably supports the top ring shaft 111 via a bearing 126, a ball screw 132 attached to the bridge 128, a support stand 129 supported by a support pillar 130, and a servo motor 138 provided on the support stand 129.

The ball screw 132 includes a screw shaft 132a connected to the servo motor 138, and a nut 132b in which the screw shaft 132a is screwed. The top ring shaft 111 moves up and down integrally with the bridge 128. Accordingly, when the servo motor 138 drives, the bridge 128 moves up and down via the ball screw 132, and thereby the top ring shaft 111 and the top ring 31 are moved up and down.

Further, the top ring shaft 111 is connected to a rotary cylinder 112 via a key (not shown). This rotary cylinder 112 includes a timing pulley 113 on an outer peripheral portion thereof. A top ring rotary motor 114 is fixed to the top ring head 110, and the above-described timing pulley 113 is connected to a timing pulley 116 provided at the top ring rotary motor 114 via a timing belt 115. Accordingly, by rotationally driving the top ring rotary motor 114, the rotary cylinder 112 and the top ring shaft 111 are integrally rotated via the timing pulley 116, the timing belt 115, and the timing pulley 113, and the top ring 31 is rotated. The top ring rotary motor 114 includes an encoder 140. The encoder 140 has a function of detecting a rotation angle position of the top ring 31 and a function of integrating the number of rotations of the top ring 31. Further, a sensor that detects a rotation angle “reference position (0 degrees)” of the top ring 31 may be additionally provided. Note that the top ring head 110 is supported by a top ring head shaft 117 rotatably supported by a frame (not shown). The top ring rotary motor 114, the servo motor 138, and the encoder 140 and other equipment within the apparatus are controlled by the controller 5.

In the first polishing module 3A configured as shown in FIG. 2, the top ring 31 can hold a substrate such as the wafer W on an undersurface thereof. The top ring head 110 is configured to be rotatable around the top ring head shaft 117, and the top ring 31 holding the wafer W on the undersurface is moved to above the polishing table 30 from the receiving position of the wafer W by rotation of the top ring head 110. Then, the top ring 31 is lowered to press the wafer W to the surface (polishing surface) 10a of the polishing pad 10. At this time, the top ring 31 and the polishing table 30 are respectively rotated, and a polishing liquid is supplied onto the polishing pad 10 from the polishing liquid supply nozzle 32 provided above the polishing table 30. In this way, the wafer W is brought into sliding contact with the polishing surface 10a and the surface of the wafer W is polished.

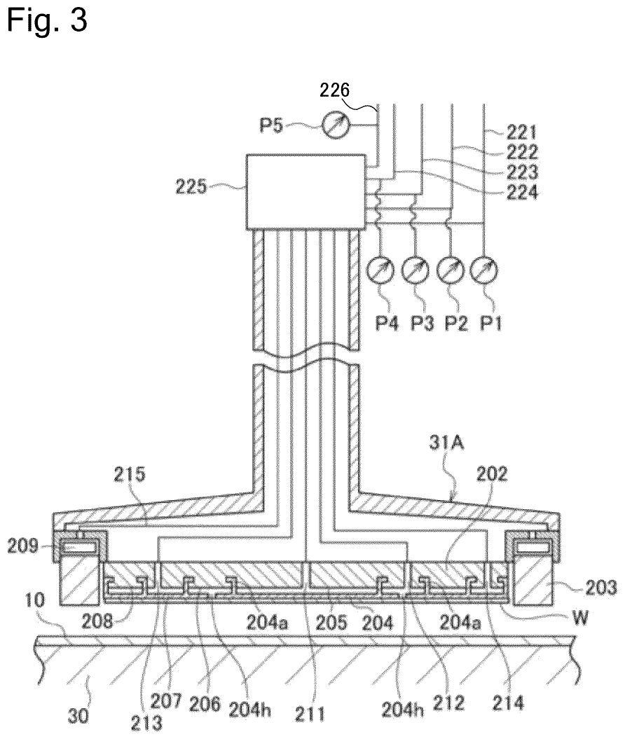

Next, the top ring (substrate holding device) 31 will be described in more detail. FIG. 3 is a schematic sectional view of the top ring 31 that composes the substrate holding device that holds the wafer W to be polished and presses the wafer W to the polishing surface on the polishing table. In FIG. 3, only main components composing the top ring 31 are shown.

As shown in FIG. 3, the top ring 31 includes the top ring body 202 that presses the wafer W to the polishing surface 10a, and the retainer ring 203 that directly presses the polishing surface 10a. The top ring body 202 is formed of a substantially disk-shaped member, and the retainer ring 203 is attached to an outer peripheral portion of the top ring body 202. The top ring body 202 is formed of a resin such as engineering plastics (for example, PEEK). A membrane (elastic film) 204 that abuts on a back surface of a wafer is attached to an undersurface of the top ring body 202. The membrane 204 defines a pressure chamber, and an undersurface thereof defines a substrate holding surface that is in contact with the wafer W. The membrane 204 is formed of a rubber material excellent in strength and durability such as ethylene propylene rubber (EPDM), polyurethane rubber, and silicon rubber.

As an example, in the example shown in FIG. 3, the membrane 204 has a plurality of concentrical partition walls 204a, and by these partition walls 204a, a circular center chamber 205, an annular ripple chamber 206, an annular outer chamber 207, and an annular edge chamber 208 are formed between a top surface of the elastic film 204 and the undersurface of the top ring body 202. That is to say, the center chamber 205 is formed in a center portion of the top ring body 202, and the ripple chamber 206, the outer chamber 207, and the edge chamber 208 are formed concentrically in order from the center to an outer periphery direction. The membrane 204 has a plurality of holes 204h that are for sucking a wafer and penetrate through the clastic film in a thickness direction of the elastic film, in a ripple area (ripple chamber 206). In the example shown in FIG. 3, the hole 204h is provided in the ripple area, but may be provided outside the ripple area. Further, in the example shown in FIG. 3, the membrane 204 has a plurality of concentrical partition walls 204a, but regardless of the example like this, the partition walls may be provided to divide a plurality of regions in a circumferential direction, or the membrane 204 may not have the partition walls 204a.

In the top ring body 202, a passage 211 communicating with the center chamber 205, a passage 212 communicating with the ripple chamber 206, a passage 213 communicating with the outer chamber 207, and a passage 214 communicating with the edge chamber 208 are respectively formed. The respective passages 211 to 214 are respectively connected to passages 221 to 224 that are connected to a vacuum source and a pressure adjuster not shown via a rotary joint 225.

Further, a retainer ring pressing chamber 209 formed of then elastic film is also formed directly above the retainer ring 203, and the retainer ring pressing chamber 209 is connected to a passage 226 via a passage 215 formed in the top ring body (carrier) 202 and the rotary joint 225. The passage 226 is connected to the vacuum source and the pressure adjuster not shown.

In the top ring 31 like this, pressure inside the center chamber 205, the ripple chamber 206, the outer chamber 207, the edge chamber 208, and the retainer ring pressing chamber 209 can be respectively adjusted independently by the vacuum source and the pressure adjuster. By the structure like this, it is possible to adjust a pressing force that presses the wafer W to the polishing pad 10 for each region of the wafer W, and adjust a pressing force with which the retainer ring 203 presses the polishing pad 10.

A series of polishing steps by the substrate processing apparatus configured as shown in FIG. 1 to FIG. 3 will be described. The top ring 31 receives the wafer W from the first linear transporter 6 and holds the wafer W by vacuum suction. The membrane 204 is provided with the plurality of holes 204h for vacuum-sucking the wafer W, and these holes 204h are connected to the vacuum source not shown. The top ring 31 holding the wafer W by vacuum suction lowers to a set position at a polishing time of the top ring which is previously set. At the set position at the polishing time, the retainer ring 203 is in contact with the surface (polishing surface) 10a of the polishing pad 10, but since the wafer W is sucked and held by the top ring 31 before polishing, there is a very small gap (for example, approximately 1 mm) between the undersurface (surface to be polished) of the wafer W and the surface of (polishing surface) of the polishing pad 10. Subsequently, the polishing table 30 and the top ring 31 are both rotationally driven. In this state, the membrane 204 on a back surface side of the wafer W is swelled, the undersurface (surface to be polished) of the wafer is brought into contact with the surface (surface to be polished) of the polishing pad 10, and by relatively moving the polishing table 30 and the top ring 31, polishing is performed until the front surface (polished surface) of the wafer W is brought into a predetermined state (for example, a predetermined film thickness).

After end of the wafer processing steps on the polishing pad 10, the wafer W is sucked by the top ring 31, the top ring 31 is raised, and moved to a substrate delivery device 800 of the first linear transporter 6, and detachment (release) of the wafer W is performed. Note that in the present embodiment, the first linear transporter 6, the second linear transporter 7, or substrate delivery devices 800 owned by them, which perform detachment of the wafer W corresponds to an example of a “transfer stage”.

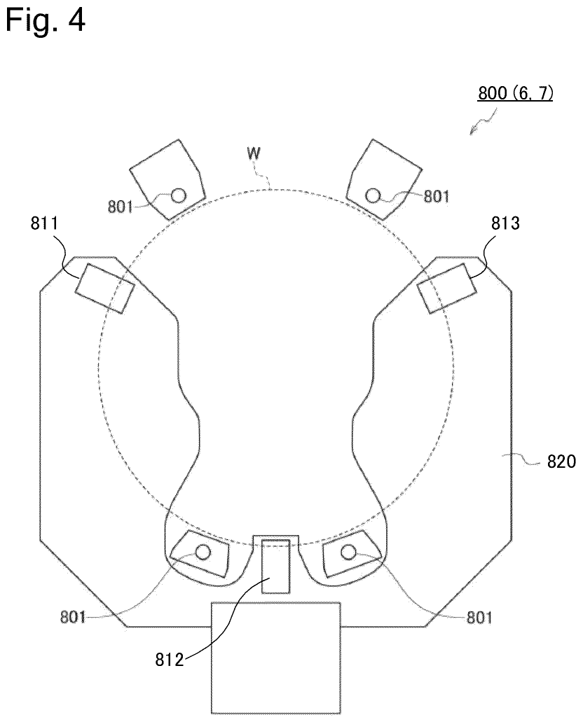

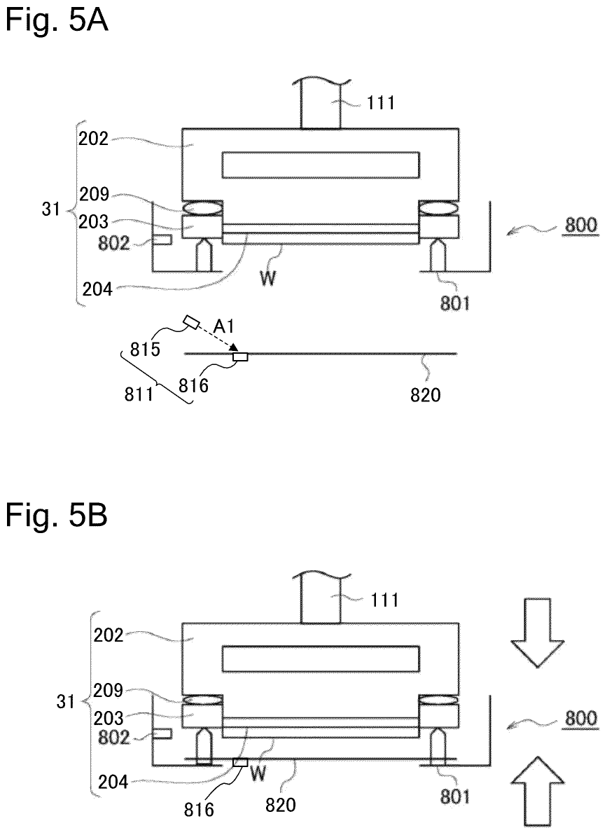

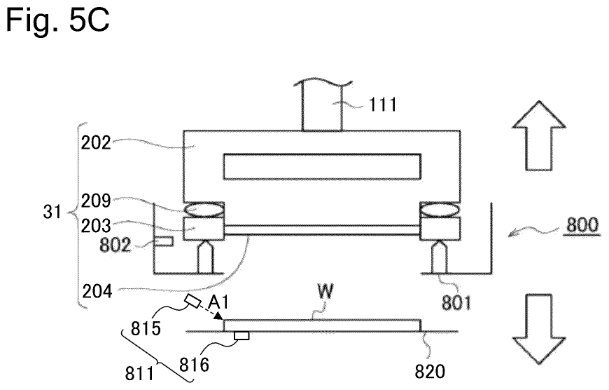

FIG. 4 is a schematic view showing the substrate delivery device 800 from above, and FIGS. 5A to 5C are schematic views showing a delivery process of the wafer W to the substrate delivery device 800 from the top ring 31. The substrate delivery device 800 includes a placement surface 820 for placing the wafer W. Further, the substrate delivery device 800 has a push-up pin 801 that pushes up the retainer ring 203 of the top ring 31. The placement surface 820 and the push-up pin 801 are configured to be able to move up and down by power sources not shown such as air cylinders respectively.

Further, the substrate delivery device 800 of the present embodiment includes three sensors 811 to 813 for detecting that the wafer W is delivered from the top ring 31 to the placement surface 820 (substrate delivery device 800). The sensors 811 to 813 are disposed to be spaced apart from one another in the circumferential direction of the wafer W so as to detect different sites of the wafer W. Detection signals by the sensors 811 to 813 are inputted to the controller 5. Note that the substrate delivery device 800 is not limited to the one having the three sensors 811 to 813 for detecting that the wafer W is delivered, but may have one sensor, two sensors, or four or more sensors. Further, as the sensors 811 to 813, optical sensors are adopted in the present embodiment, but sensors using magnetism, mechanical switches and the like may be adopted.

As shown in FIG. 5A, as an example, the sensor 811 includes a light emitter 815 and a light receiver 816. Note that although the sensors 812 and 813 are not shown in FIG. 5A to FIG. 5C, the sensors 812 and 813 includes similar configurations to that of the sensor 811. The light emitter 815 is, for example, a fiber sensor in which a flexible optical fiber cable is used in a light emitter of an optoelectronic sensor, and a detection head is miniaturized. The light receiver 816 is, for example, a fiber sensor in which a flexible optical fiber cable is used in a light receiver of an optoelectronic sensor, and a detection head is miniaturized.

The light emitter 815 emits light in a direction of an arrow Al (see FIG. 5A). When the wafer W is not removed from the top ring 31, the light receiver 816 can receive light emitted from the light emitter 815. On the other hand, when the wafer W is detached from the top ring 31 and is delivered to the placement surface 820 as shown in FIG. 5C, light emitted from the light emitter 815 is shielded by the wafer W, and the light receiver 816 cannot detect the light. The controller 5 deals a time when the light cannot be detected in the light receiver 816, or a time when light intensity detected by the light receiver 816 becomes lower than a threshold value, as the time when the wafer W is detected. Note that the light source of the light emitter 815 is an LED, for example, and a color of the light may be any color (for example, red, blue, green, white, or the like).

Further, the substrate delivery device 800 of the present embodiment has, for example, three release nozzles 802 facing inward (wafer W side) (see FIG. 5A to FIG. 5C). The release nozzles 802 are connected to a pressurized fluid supply source not shown, and ejection of the pressurized fluid is controlled by the controller 5. However, the substrate delivery device 800 may have one, two, or four or more release nozzles, or may have no release nozzle.

Hereinafter, an operation of delivering the wafer W from the top ring 31 to the placement surface 820 will be described. After the end of the wafer processing steps on the polishing pad 10, the top ring 31 moves to the substrate delivery device 800 in a state where the top ring 31 sucks the wafer W (see FIG. 5A), and performs detachment (release) of the wafer W. Note that after moving to the substrate delivery device 800, a cleaning operation may be performed by rotating the top ring 31 while pure water and a chemical solution is supplied to the wafer W sucked and held by the top ring 31,

After the top ring 31 moves to the substrate delivery device 800, the top ring 31 lowers, and the placement surface 820 rises. Thereby, the placement surface 820 approaches the undersurface of the wafer W, but both of them do not contact each other. Further, by lowering of the top ring 31, the push-up pin 801 pushes up the retainer ring 203 (see FIG. 5B). In this state, the ripple chamber 206 of the membrane 204 is swelled, and vacuum suction of the wafer W is stopped to perform a wafer detachment operation. At this time, a pressurized fluid can be injected to the gap between the membrane 204 and the wafer W from the release nozzle 802. As the pressurized fluid, at least one of pressurized gas (for example, pressurized nitrogen) and a pressurized liquid (for example, pure water) can be used.

When the wafer W is placed on the placement surface 820, the wafer W is detected by the sensors 811 to 813. When all the sensors 811 to 812 detect the wafer W, the controller 5 determines that delivery of the wafer W from the top ring 31 to the placement surface 820 is completed. Thereafter, the placement surface 820 on which the wafer W is placed lowers, the top ring 31 rises, and the delivery of the wafer W is completed (see FIG. 5C).

Next, a method for determining a state of the membrane (elastic film) 204 by the controller 5 will be described. The controller 5 includes a CPU, a memory (storage 59) and the like, and may be configured by a microcomputer that realizes predetermined functions by using software or may be configured by a hardware circuitry that performs dedicated arithmetic processing. Note that the controller 5 is not limited to the one configured by a single device but may be configured by a plurality of devices provided to be spaced apart from one another, as an example. Here, in the present embodiment, the controller 5 that determines the state of the membrane 204 corresponds to an example of an “information processing apparatus”, and the state determination of the membrane 204 that is executed by the controller 5 corresponds to an example of an “information processing method”. However, the “information processing apparatus” is not limited to the controller 5 provided in the substrate processing apparatus, but may be configured by an external computer or the like configured to be communicable with the controller 5, as an example.

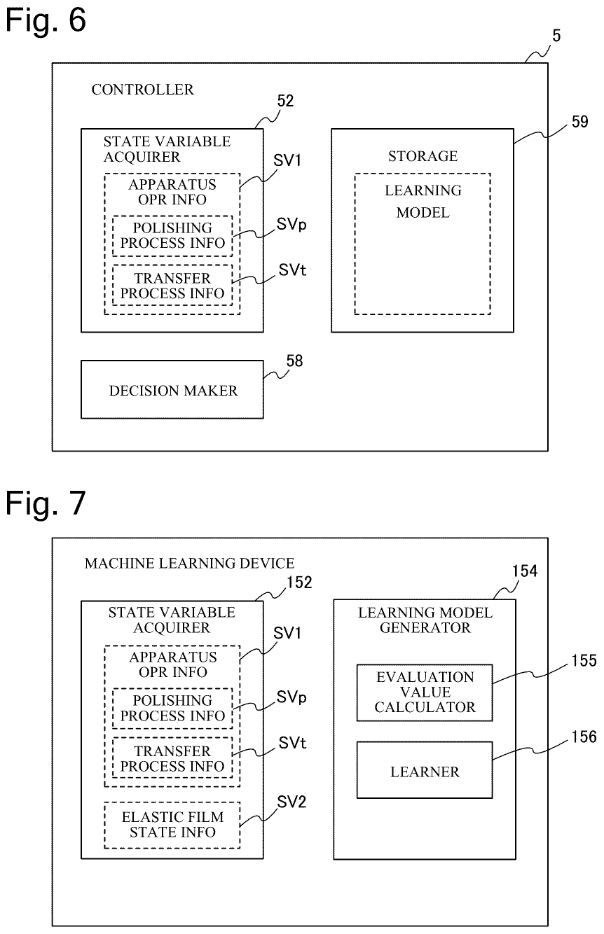

FIG. 6 is a schematic functional block diagram of the controller 5 in the present embodiment. The controller 5 includes a state variable acquirer 52 that acquires a state variable (device operation information SV1), the storage 59 in which a learning model is stored, and a decision maker 58 that outputs (makes decision) the state of the membrane 204 based on the acquired state variable (apparatus operation information SV1) and the learning model. Here, in the present embodiment, the state variable acquirer 52 corresponds to an example of the “information acquirer”, and the decision maker 58 corresponds to an example of a “state determiner”.

In the present embodiment, the learning model stored in the storage 59 is constructed by a machine learning device. As an example, the substrate processing apparatus acquires the learning model constructed by being machine-learned in the machine learning device by wired or wireless communication and stores the learning model in the storage 59. Alternatively, the substrate processing apparatus may be loaded with the storage 59 in which the learning model constructed by the machine learning device is previously stored. In the present embodiment, the machine learning device is shown as a separate component from the controller 5, but the controller 5 may perform a function of at least a part of the machine learning device. The machine learning device may be configured by a microcomputer that includes a CPU, a memory and the like, and realizes predetermined functions by using software, or may be configured by a hardware circuitry that performs dedicated arithmetic processing. FIG. 7 is a schematic functional block diagram of the machine learning device in the present embodiment. The machine learning device includes a state variable acquirer 152 that acquires state variables (the apparatus operation information SV1, clastic film state information SV2) as learning data, and a learning model generator 154 that learns and generates learning models based on the acquired state variables.

The state variable acquirer 152 of the machine learning device acquires the apparatus operation information SV1 of the substrate processing apparatus, and the elastic film state information SV2 showing the state of the membrane 204 used in the top ring 31 when the top ring (substrate holding device) 31 operates by the operation shown by the apparatus operation information SV1. The apparatus operation information SV1 can be acquired through the controller 5. The apparatus operation information SV1 includes polishing process information SVp by the top ring 31, and transfer process information SVt by the top ring 31. Here, the polishing process information SVp and the transfer process information SVt may be respectively measured by various sensors, or may show control commands by the controller 5.

The polishing process information SVp by the top ring 31 can include the number of wafers W processed by the membrane 204, or a usage time period of the membrane 204. Further, the polishing process information SVp can include pressure of at least one (hereinafter, also simply referred to a “pressure chamber of the membrane 204”) of the center chamber 205, the ripple chamber 206, the outer chamber 207, and the edge chamber 208 (in the polishing process) at the time of pressing the wafer W to the polishing pad 10 by the top ring 31, or a flow rate of the fluid that is supplied to the pressure chamber of the membrane 204. Further, the polishing process information SVp can include at least one of the rotational speed of the top ring 31 in the polishing process, rotation torque of the top ring 31 in the polishing process, a swing position (moving position) of the top ring 31 in the polishing process, a height position of the top ring 31 (height position of the top ring 31 with respect to the polishing table 30) in the polishing process, an up-down movement (rising and lowering) power of the top ring 31 by the up-down movement mechanism 124, pressure of the retainer ring pressing chamber 209 in the polishing process, and a flow rate of the fluid that is supplied to the retainer ring pressing chamber 209 in the polishing process. Further, the polishing process information SVp can include at least one of the rotational speed of the polishing pad 10 in the polishing process, rotation torque of the polishing pad 10 in the polishing process, a surface temperature of the polishing pad 10, and the surface properties of the polishing pad 10. For the surface temperature of the polishing pad 10 and the surface properties of the polishing pad 10, the information detected by contact or non-contact sensors can be used. Further, the polishing process information SVp includes at least one of a supply amount of a polishing liquid, a supply position, and a temperature of the polishing liquid by the polishing liquid supply nozzle 32 in polishing process. These pieces of the polishing process information SVp are the information showing the state of the polishing process using the membrane 204. Here, as the polishing process information SVp, a polishing recipe (control command values) by the controller 5 may be used, or detection values detected by various sensors included in the substrate processing apparatus may be used. The use of the polishing process information SVp is based on the belief that the state of the membrane 204 changes according to the conditions of the polishing process, and that the state of the membrane 204 affects the state of the polishing process.

The transfer process information SVt by the top ring 31 can include at least one of a detachment time per one wafer by a detachment operation of the wafer W from the top ring 31, the number of detachment operations of the wafers W using the membrane 204, and pressure of the pressing chamber of the membrane 204 during the detachment operation of the wafer W. In the present embodiment, a time taken for the detachment operation of the wafer W that is detected by the respective sensors 811 to 813 is referred to as a “detachment time” or “seating time”. Here, as the detachment time by the detachment operation of the wafer W, times after the pressurized fluid is ejected from the release nozzle 802 until seating of the wafer W is detected by the plurality of sensors 811 to 813 can be used, for example. Further, in this case, seating times detected by the respective sensors 811 to 813 may be used, or an average of the seating times (also called an “average seating time tm”) detected by the respective sensors 811 to 813 may be used. Furthermore, the transfer process information SVt can include a time difference At in seating timings detected by the respective sensors 811 to 813. The time difference At in the seating timings may be acquired by calculating a difference in detachment time detected by the respective sensors 811 to 813, or may be acquired by calculating difference in the seating timings detected by the respective sensors 811 to 813. Further, the transfer process information SVt by the top ring 31 can include at least one of an injection flow rate, injection pressure, an injection time, and an injection angle of the pressurized fluid injected from the release nozzle 802. In the top ring 31 of the present embodiment, the membrane 204 is used to transfer the wafer W. The transfer process information SVt is information showing the state of the transfer process of the wafer W using the membrane 204. Here, as the transfer process information SVt, a transfer recipe (control command values) by the controller 5 may be used, or detection values detected by the various sensors included in the substrate processing apparatus may be used. The use of the transfer process information SVt is based on the belief that the state of the membrane 204 changes according to the conditions of the transfer process, and the state of the membrane 204 affects the state of the transfer process.

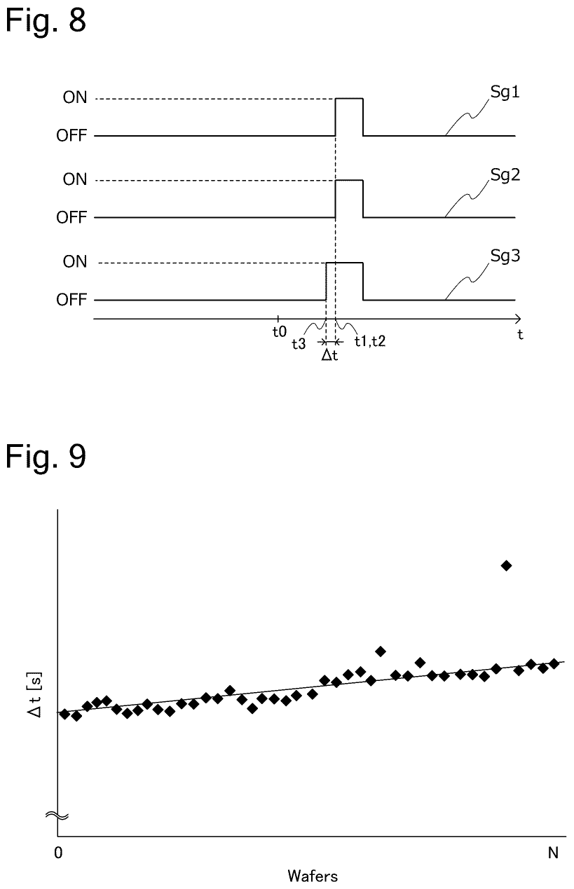

FIG. 8 is a time chart showing an example of detection signals of the respective sensors at the time of detaching the wafer. FIG. 8 shows detection signals Sg1 to Sg3 by the sensors 811 to 813. The detection signals Sg1 to Sg3 of the present embodiment are “OFF” when the wafer W is not detected by the sensors 811 to 813, and are “ON” when the wafer W is detected by the sensors 811 to 813. Note that in FIG. 8, when the wafer W is detected by all the sensors 811 to 813, light emission from the light emitter 815 is stopped, and the detection signals Sg1 to Sg3 are “OFF”. As shown in the time chart, in normal delivery of the wafer W, after a time t at which the detachment operation of the wafer W is started, the detection signal Sg3 turns “ON” first (timing t3), and the detection signals Sg1 an Sg2 turn “ON” a short time later (timings t1, t2). FIG. 9 is a diagram showing an example of a time difference in seating timing of each of wafers. In FIG. 9, the horizontal axis represents the number of wafers W that have been dealt after the new membrane 204 was used. The vertical axis represents the time difference Δt in the seating timing at the time of each of the wafers W being delivered from the top ring 31 to the delivery device 800. Note that the time difference Δt in the seating timing is a time difference Δt between an earliest timing at which the wafer W is detected by the plurality of sensors 811 to 813 (an example of a “first timing”) and a latest timing at which the wafer W is detected (an example of a “second timing”). Other than this, the time difference At in the seating timing may be a time difference in seating timings that are detected respectively by any two sensors of the sensors 811 to 813. As shown in the diagram, based on the study by the present inventors, it is known that when the state of the membrane 204 is bad, the time difference At in the timings t1 to t3 detected by the respective sensors 811 to 813 tends to be large.

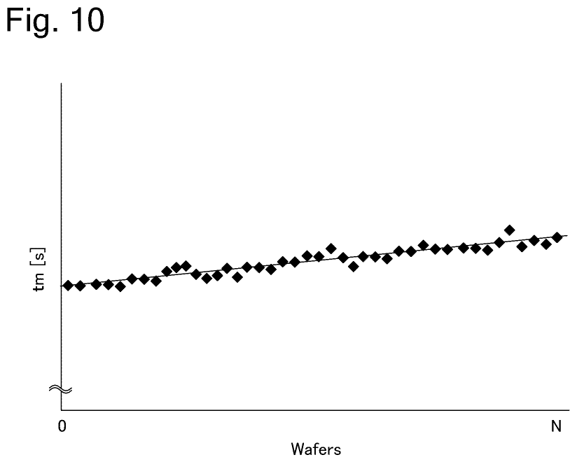

FIG. 10 is a diagram schematically showing an example of a detachment time of each of the wafers. In FIG. 10, the horizontal axis represents the number of wafers W dealt after the new membrane 204 was used. The vertical axis represents a seating time (average detachment time tm) at the time of each of the wafers being delivered from the top ring 31 to the delivery device 800. Based on the study by the present inventors, it is known that as the number of the dealt wafers W increases and the state of the membrane 204 becomes worse, the time taken for the detachment operation of the wafer W from the top ring 31 gradually changes, becoming longer or shorter. In the example shown in FIG. 10, as the number of dealt wafers W increases, the time (average detachment time tm) taken for the detachment operation of the wafer W from the top ring 31 gradually becomes longer.

The clastic film state information SV2 is the information showing the state of the membrane 204 as a result of the top ring 31 being operated in the operation shown by the apparatus operation information SV1 described above. For the elastic film state information SV2, the state of the membrane 204 detected by the various sensors included in the controller 5 may be used. Further, the clastic film state information SV2 may be acquired by the membrane 204 that is being used or after use being measured by additional sensors or the like provided for the substrate processing apparatus, or in a manufacturing plant or dedicated learning facility.

The elastic film state information SV2 can include at least one of captured image data of the membrane 204 captured by an image capturer, surface roughness of the membrane 204, and an elastic modulus of the membrane 204. Here, as the image capturer, various image capturers including known image capturers can be used. Further, the surface roughness and the clastic modulus of the membrane 204 that are measured by contacting or non-contacting the membrane 204 can be used. These pieces of clastic film state information SV2 may be acquired with respect to the entire region of the membrane 204, or a preset site.

The learning model generator 154 learns a learning model (correlation between the apparatus operation information SV1 and the elastic film state information SV2) in accordance with an optional learning algorithm generally referred to as machine learning. The learning model generator 154 repeatedly executes learning based on the state variables (the apparatus operation information SV1 and the clastic film status information SV2) acquired by the state variable acquirer 142. The learning model generator 154 acquires a plurality of state variables, identifies the characteristics of the state variables and interprets the correlations.

In the present embodiment, the learning model generator 154 is a teacher, and constructs a learning model by learning. Further, the learning model generator 154 may execute reinforcement learning and learn the learning model. The reinforcement learning is a method of giving a reward to a behavior (output) executed with respect to a present state (input) and generating a learning model that can obtain a maximum reward in a certain environment. As an example of performing the reinforcement learning, the learning model generator 154 has an evaluation value calculator 155 that calculates an evaluation value based on the state variable SV, and a learner 156 that performs learning of the learning model based on the evaluation value. As an example, the evaluation value calculator 155 may give a larger reward as the time taken for processing of the wafer W in the substrate processing apparatus is shorter. Further, as an example, the evaluation value calculator 155 may give a larger reward as the polishing process of the wafer W is more constant.

Explanation will be made by referring to FIG. 6 once again. The decision maker 58 of the controller 5 determines the state of the membrane 204 based on the learning model constructed by machine learning, and the apparatus operation information SV1 acquired by the state information acquirer 52 of the controller 5. Here, the state information acquirer 52 of the controller 5 can acquire the apparatus operation information SV1 similarly to the state variable acquirer 152 of the machine learning device. However, the apparatus operation information SV1 acquired by the state information acquirer 52 of the controller 5 may be different from the apparatus operation information SV1 that is acquired by the state variable acquirer 152 of the machine learning device.

The decision maker 58 can output information similar to the elastic film state information SV2 that is inputted to the machine learning device as the state of the membrane 204. Further, the decision maker 58 may show a deterioration degree of the membrane 204 in numbers or the like based on the elastic film state information SV2 so that a user of the substrate processing apparatus can easily understand it, instead of, or in addition to the elastic film state information SV2. Alternatively, the decision maker 58 may output a durable period or a durable number of uses before replacement of the membrane 204 is recommended based on the clastic film state information SV2.

As described above, the apparatus operation information SV1 including the polishing process information SVp and the transfer process information SVt by the top ring 31, and the elastic film state information SV2 showing the state of the membrane 204 at the time of the top ring 31 being operated in the operation shown by the apparatus operation information SV1 are inputted, and the learning model is constructed by machine learning. Then, the controller 5 of the substrate processing apparatus inputs the apparatus operation information SV1 to the learning model stored in the storage 59, causes the learning model to output the elastic film state information SV2, and thereby determines the state of the membrane 204. As a result, it is possible to determine the state of the membrane 204 properly or easily and perform substrate processing in the substrate processing apparatus.

The present invention can also be described as the following modes.
[Mode 1] According to mode 1, there is proposed an information processing apparatus including an information acquirer that acquires apparatus operation information including polishing process information showing a state of a polishing process, and transfer process information showing a state of a transfer process, as an operation state at a time of a substrate processing apparatus being operated, the substrate processing apparatus including a polishing table that supports a polishing pad, a top ring including an elastic film composing a substrate holding surface and a pressure chamber, and a transfer stage configured so that a substrate is delivered thereto from the top ring, and performing the polishing process of pressing the substrate to the polishing pad according to a fluid supplied to the pressure chamber, and the transfer process of detaching the substrate from the elastic film and delivering the substrate to the transfer stage, and a state determiner that determines elastic film state information with respect to the apparatus operation information by inputting the apparatus operation information acquired by the information acquirer to a learning model that is caused to learn, by machine learning, a correlation between the apparatus operation information, and the elastic film state information showing a state of the clastic film at a time of the polishing process and/or the transfer process shown by the apparatus operation information being performed. According to mode 1, it is possible to properly or easily determine the state of the clastic film.
[Mode 2] According to mode 2, in mode 1, the clastic film state information includes at least one of captured image data of the elastic film that is captured by an image capturer, surface roughness of the clastic film, and an elastic modulus of the elastic film. According to mode 2, it is possible to properly determine the state of the elastic film.
[Mode 3] According to mode 3, in mode 1 or 2, the clastic film state information includes a durable period or a durable number of uses before the elastic film is replaced. According to mode 3, it is possible to determine the durable period or the durable number of uses of the clastic film.
[Mode 4] According to mode 4, in modes 1 to 3, the transfer process information includes at least one of a detachment time per one substrate by the transfer process, a number of times of the transfer process, and pressure in the pressure chamber at a time of the transfer process. According to mode 4, it is possible to properly determine the state of the clastic film.
[Mode 5] According to mode 5, in mode 4, the substrate processing apparatus includes a first sensor and a second sensor that detect that the substrate is delivered to the transfer stage, the first sensor and the second sensor are disposed to detect different sites of the substrate, and the transfer process information includes a first detachment time at which the first sensor detects that the substrate is delivered to the transfer stage, and a second detachment time at which the second sensor detects that the substrate is delivered to the transfer stage. According to mode 5, it is possible to determine the state of the clastic film based on the detection information by the plurality of sensors that detect that the substrate is delivered to the transfer stage.
[Mode 6] According to mode 6, in mode 4 or 5, the substrate processing apparatus includes a first sensor and a second sensor that detect that the substrate is delivered to the transfer stage, the first sensor and the second sensor are disposed to detect different sites of the substrate, and the transfer process information includes a time difference between a first timing at which the first sensor detects that the substrate is delivered to the transfer stage, and a second timing at which the second sensor detects that the substrate is delivered to the transfer stage. According to mode 6, it is possible to determine the state of the clastic film based on the detection information by the plurality of sensors that detect that the substrate is delivered to the transfer stage.
[Mode 7] According to mode 7, in modes 4 to 6, the substrate processing apparatus includes a release nozzle configured to inject a pressurized fluid to a gap between the substrate holding surface and the substrate at a time of the transfer process, and the transfer process information includes at least one of an injection flow rate, injection pressure, an injection time, and an injection angle of the pressurized fluid injected from the release nozzle. According to mode 7, it is possible to determine the state of the elastic film based on the operation information of the release nozzle.
[Mode 8] According to mode 8, in modes 1 to 7, the apparatus operation information includes usage history information of the clastic film, and the usage history information of the clastic film includes at least one of a number of substrates processed by using the elastic film, and a usage time period of the clastic film. According to mode 8, it is possible to properly determine the state of the elastic film.
[Mode 9] According to mode 9, in modes 1 to 8, the polishing process information includes at least one of pressure in the pressure chamber at a time of the substrate being pressed to the polishing pad by the top ring, and a flow rate of the fluid supplied to the pressure chamber. According to mode 9, it is possible to properly determine the state of the clastic film.
[Mode 10] According to mode 10, in mode 9, the top ring is configured to press the substrate to the polishing pad with rotation and/or movement of the substrate holding surface, and the polishing process information includes at least one of a rotational speed of the substrate holding surface, rotation torque for rotating the substrate holding surface, a moving position of the substrate holding surface, power for moving the substrate holding surface, a height position of the top ring with respect to the polishing table, rising and lowering power of the top ring, pressure in a pressing chamber of a retainer ring included by the top ring, and a supply flow rate into the pressing chamber of the retainer ring. According to mode 10, it is possible to properly determine the state of the elastic film.
[Mode 11] According to mode 11, in modes 1 to 10, the polishing process information includes at least one of a polishing liquid supply flow rate by a polishing liquid supply nozzle configured to supply a polishing liquid to the polishing pad, a polishing liquid supply position, and a polishing liquid temperature. According to mode 11, it is possible to properly determine the state of the elastic film.
[Mode 12] According to mode 12, in modes 1 to 11, the top ring is configured to press the substrate to the polishing pad with rotation of the polishing table, and the polishing process information includes at least one of a rotational speed of the polishing table, rotation torque for rotating the polishing table, a surface temperature of the polishing pad, and surface properties of the polishing pad. According to mode 12, it is possible to properly determine the state of the elastic film.
[Mode 13] According to mode 13, there is proposed a substrate processing apparatus including a polishing table that supports a polishing pad, a top ring including an elastic film composing a substrate holding surface and a pressure chamber, a transfer stage configured so that a substrate is delivered thereto from the top ring, and the information processing apparatus according to modes 1 to 12. According to mode 13, it is possible to exhibit the same effects as the effects of modes 1 to 12 in the substrate processing apparatus.
[Mode 14] According to mode 14, there is proposed an information processing method including an information acquiring step of acquiring apparatus operation information including polishing process information showing a state of a polishing process, and transfer process information showing a state of a transfer process, as an operation state at a time of a substrate processing apparatus being operated, the substrate processing apparatus including a polishing table that supports a polishing pad, a top ring including an elastic film composing a substrate holding surface and a pressure chamber, and a transfer stage configured so that a substrate is delivered thereto from the top ring, and performing the polishing process of pressing the substrate to the polishing pad according to a fluid supplied to the pressure chamber, and the transfer process of detaching the substrate from the elastic film and delivering the substrate to the transfer stage, and a state determination step of determining an elastic film state information with respect to the apparatus operation information by inputting the apparatus operation information acquired by the information acquirer to a learning model that is caused to learn, by machine learning, a correlation between the apparatus operation information, and the elastic film state information showing a state of the elastic film at a time of the polishing process and/or the transfer process shown by the apparatus operation information being performed. According to mode 14, it is possible to properly or easily determine the state of the elastic film.

Although the embodiments of the present invention are described above, the above-described embodiments of the invention are to facilitate understanding of the present invention, and are not intended to limit the present invention. It goes without saying that the present invention can be changed and altered without departing from the gist of the invention, and the present invention includes the equivalents thereof. Further, within the range in which at least a part of the aforementioned problem can be solved, or in the range in which at least a part of the effect is exhibited, any combination of the embodiments and modifications is possible, and any combination or omission of the respective components described in the claims and description is possible.

The present application is based upon and claims the benefit of Japanese Patent Application No. 2023-137892 filed on Aug. 28, 2023. The entire contents of the disclosure including the description, the claims, the drawings and the abstract of Japanese Patent Application No. 2023-137892 are incorporated herein by reference. The entire disclosure including the description, the claims, the drawings and the abstract of Japanese Patent Laid-Open No. 2012-178608 (Patent Literature 1) is herein incorporated in its entirety by reference.

### REFERENCE SIGNS LIST

W wafer
2 load port
3 (3A to 3D) polishing module
4 cleaning module
5 controller
6 first linear transporter
7 second linear transporter
10 polishing pad
10a polishing surface
22 transfer robot
30 polishing table
31 top ring (substrate holding device)
32 polishing liquid supply nozzle
52 state variable acquirer
58 decision maker
59 storage
152 state variable acquirer
154 learning model generator
155 evaluation value calculator
156 learner
202 top ring body
203 retainer ring
204 membrane (clastic film)
205 center chamber
206 ripple chamber
207 outer chamber
208 edge chamber
209 retainer ring pressing chamber
800 substrate delivery device
801 push-up pin
802 release nozzle
811 to 813 sensor
820 placement surface

What is claimed is:

1. An information processing apparatus comprising:
an information acquirer that acquires apparatus operation information including polishing process information showing a state of a polishing process, and transfer process information showing a state of a transfer process, as an operation state at a time of a substrate processing apparatus being operated, the substrate processing apparatus including a polishing table that supports a polishing pad, a top ring including an elastic film composing a substrate holding surface and a pressure chamber, and a transfer stage configured so that a substrate is delivered thereto from the top ring, and performing the polishing process of pressing the substrate to the polishing pad according to a fluid supplied to the pressure chamber, and the transfer process of detaching the substrate from the elastic film and delivering the substrate to the transfer stage; and
a state determiner that determines elastic film state information with respect to the apparatus operation information by inputting the apparatus operation information acquired by the information acquirer to a learning model that is caused to learn, by machine learning, a correlation between the apparatus operation information, and the elastic film state information showing a state of the elastic film at a time of the polishing process and/or the transfer process shown by the apparatus operation information being performed.

2. The information processing apparatus according to claim 1, wherein the elastic film state information includes at least one of captured image data of the elastic film, surface roughness of the elastic film, and an elastic modulus of the elastic film.

3. The information processing apparatus according to claim 1, wherein the elastic film state information includes a durable period or a durable number of uses before the elastic film is replaced.

4. The information processing apparatus according to claim 1, wherein the transfer process information includes at least one of a detachment time per one substrate by the transfer process, a number of times of the transfer process, and pressure in the pressure chamber at a time of the transfer process.

5. The information processing apparatus according to claim 4, wherein
the substrate processing apparatus includes a first sensor and a second sensor that detect that the substrate is delivered to the transfer stage,
the first sensor and the second sensor are disposed to detect different sites of the substrate, and
the transfer process information includes a first detachment time at which the first sensor detects that the substrate is delivered to the transfer stage, and a second detachment time at which the second sensor detects that the substrate is delivered to the transfer stage.

6. The information processing apparatus according to claim 4, wherein
the substrate processing apparatus includes a first sensor and a second sensor that detect that the substrate is delivered to the transfer stage,
the first sensor and the second sensor are disposed to detect different sites of the substrate, and
the transfer process information includes a time difference between a first timing at which the first sensor detects that the substrate is delivered to the transfer stage, and a second timing at which the second sensor detects that the substrate is delivered to the transfer stage.

7. The information processing apparatus according to claim 4, wherein
the substrate processing apparatus includes a release nozzle configured to inject a pressurized fluid to a gap between the substrate holding surface and the substrate at a time of the transfer process, and
the transfer process information includes at least one of an injection flow rate, injection pressure, an injection time, and an injection angle of the pressurized fluid injected from the release nozzle.

8. The information processing apparatus according to claim 1, wherein
the apparatus operation information includes usage history information of the elastic film, and
the usage history information of the elastic film includes at least one of a number of substrates processed by using the elastic film, and a usage time period of the elastic film.

9. The information processing apparatus according to claim 1, wherein
the polishing process information includes at least one of pressure in the pressure chamber at a time of the substrate being pressed to the polishing pad by the top ring, and a flow rate of the fluid supplied to the pressure chamber.

10. The information processing apparatus according to claim 9, wherein
the top ring is configured to press the substrate to the polishing pad with rotation and/or movement of the substrate holding surface, and
the polishing process information includes at least one of a rotational speed of the substrate holding surface, rotation torque for rotating the substrate holding surface, a moving position of the substrate holding surface, power for moving the substrate holding surface, a height position of the top ring with respect to the polishing table, rising and lowering power of the top ring, pressure in a pressing chamber of a retainer ring included by the top ring, and a supply flow rate into the pressing chamber of the retainer ring.

11. The information processing apparatus according to claim 1, wherein the polishing process information includes at least one of a polishing liquid supply flow rate by a polishing liquid supply nozzle configured to supply a polishing liquid to the polishing pad, a polishing liquid supply position, and a polishing liquid temperature.

12. The information processing apparatus according to claim 1, wherein
the top ring is configured to press the substrate to the polishing pad with rotation of the polishing table, and
the polishing process information includes at least one of a rotational speed of the polishing table, rotation torque for rotating the polishing table, a surface temperature of the polishing pad, and surface properties of the polishing pad.

13. A substrate processing apparatus, comprising:
a polishing table that supports a polishing pad;
a top ring including an elastic film composing a substrate holding surface and a pressure chamber;
a transfer stage configured so that a substrate is delivered thereto from the top ring; and
the information processing apparatus according to claim 1.

14. An information processing method, comprising:
an information acquiring step of acquiring apparatus operation information including polishing process information showing a state of a polishing process, and transfer process information showing a state of a transfer process, as an operation state at a time of a substrate processing apparatus being operated, the substrate processing apparatus including a polishing table that supports a polishing pad, a top ring including an elastic film composing a substrate holding surface and a pressure chamber, and a transfer stage configured so that a substrate is delivered thereto from the top ring, and performing the polishing process of pressing the substrate to the polishing pad according to a fluid supplied to the pressure chamber, and the transfer process of detaching the substrate from the elastic film and delivering the substrate to the transfer stage, and
a state determination step of determining an elastic film state information with respect to the apparatus operation information by inputting the apparatus operation information acquired by the information acquirer to a learning model that is caused to learn, by machine learning, a correlation between the apparatus operation information, and the elastic film state information showing a state of the elastic film at a time of the polishing process and/or the transfer process shown by the apparatus operation information being performed.
